(19) United States
(12) Patent Application Publication
(10) Pub. No.: US 2013/0107467 A1
(43) Pub. Date: May 2, 2013

(54) CIRCUIT SUBSTRATE, ELECTRONIC DEVICE, ELECTRONIC APPARATUS, AND METHOD OF MANUFACTURING CIRCUIT SUBSTRATE

(71) Applicant: Seiko Epson Corporation, Tokyo (JP)

(72) Inventor: Hideyuki KANNO, Minowa (JP)

(73) Assignee: SEIKO EPSON CORPORATION, Tokyo (JP)

(21) Appl. No.: 13/652,685

(22) Filed: Oct. 16, 2012

(30) Foreign Application Priority Data
Oct. 28, 2011 (JP) 2011-236931

(51) Int. Cl. H05K 7/00; H05K 3/00; H05K 1/11

(52) U.S. Cl. 361/728; 174/262; 29/829

(57) ABSTRACT

A circuit substrate includes a single-layer insulating substrate, a through-hole, and wiring conductors that are provided in both main surfaces of the single-layer insulating substrate. The through-hole includes first and second concave portions that are formed in both of the main surfaces of the single-layer insulating substrate, respectively, and a through-portion through which both of the concave portions communicate with each other. An opening area of a portion at which the first and second concave portions overlap each other is a half or less of an opening area of any large concave portion between both of the concave portions, and a metallic film is formed on the respective inner wall surfaces of the first and second concave portions, and the through-portion.

### BACKGROUND

1. Technical Field

The present invention relates to a circuit substrate, a container, and an electronic device, and more particularly, to a circuit substrate, a container, and an electronic device that use a single-layer insulating substrate.

2. Related Art

Among piezoelectric oscillators, since a vibrating mode of an AT-cut quartz oscillator is a thickness sliding vibration mode, the AT-cut quartz oscillator is suitable for miniaturization and high-frequencies. In addition, since the AT-cut quartz oscillator has an excellent frequency-temperature characteristic of a cubic curve, the AT-cut quartz oscillator has been used in various fields such as electronic apparatuses. In recent years, miniaturization and lowering of the height of the piezoelectric oscillators have been further required.

JP-A-2003-179456 discloses a surface mounting container and a quartz device using the surface mounting container. This quartz device includes a quartz oscillating element having an excitation electrode, a single-layer substrate having an element-mounting electrode pad on a front surface thereof and a mounting terminal on a rear surface thereof, and a cover member having a reversed concave shape.

A through-hole is formed at a peripheral portion of the single-layer substrate to which an opening end surface of the cover member is bonded, and sealing metal is embedded in the through-hole by Au-plating. As a sealing material, glass is coated on the opening end surface of the cover member in advance in powder form, and this glass is heated, melted, and bonded to the single-layer substrate. The through-hole in which the sealing metal is embedded is covered with the glass as the sealing material and thus hermetic closing is reliably carried out.

In addition, JP-A-2004-166006 discloses a surface mounting quartz oscillator. This surface mounting quartz oscillator includes amounting substrate, a cover member having a reversed concave shape, and a quartz oscillating element. The mounting substrate has an element-mounting electrode pad (formed from a metallic film and a metallic plate) on a front surface of a silicon substrate in the vicinity of both end portions. A through-hole in which a metallic film is formed on an inner wall surface thereof penetrates through the inside of the mounting substrate, and connects the electrode pad formed on the front surface and an external terminal formed on a rear surface to each other. The cover member, which is formed from Pyrex (registered trademark) glass or the like, is brought into contact with a peripheral portion of the mounting substrate, and a negative voltage is applied while carrying out heating, whereby the mounting substrate and the cover member are air-tightly sealed by anodic bonding. In this container, a frame width of an opening of the cover member may be made narrower than that of a laminated ceramic container in the related art and thereby an area of the inner bottom surface of the container may be increased. Therefore, a large quartz oscillating element may be used.

In addition, JP-A-2011-124978 discloses a surface mounting-type quartz oscillator. The quartz oscillator includes an insulating substrate, a quartz oscillating element, and a cover member. A quartz maintaining terminal formed from an Ag—Pd alloy is provided to be opposite to the vicinity of both end portions of a surface of an insulating substrate (a ceramic base), and mounting terminals are formed at respective corner portions of a rear surface. Lead-out terminals are formed to face the respective closest corners from an end portion of the quartz maintaining terminal and are connected to a castellation electrode (through-terminal). The quartz oscillating element is connected to an end portion of the quartz maintaining terminal by applying a conductive adhesive to the end portion.

The cover member is formed from a metallic material and has a reversed concave shape, and thus an opening end surface is bent into an L-shape. An insulating sealing material (resin or glass) is applied on the periphery of a surface of the insulating substrate, and the insulating substrate and the cover member are air-tightly sealed. The cover member is fixed on the insulating substrate by a resin having an insulation property and an adhesion property as the sealing material, and an opening surface of the cover member is configured not to come into contact with the lead-out terminals.

However, in the container disclosed in JP-A-2003-179456, since the through-hole is provided at the peripheral portion of the single-layer substrate and the sealing metal is embedded in the through-hole, there is a concern that many man-hours are required and thus the cost may increase. In addition, in the container disclosed in JP-A-2004-166006, since a silicon substrate is used as a mounting substrate, there is a concern that the cost of the container may be increased. In addition, since the anodic bonding is used for the sealing between the mounting substrate and the cover member, there is a problem in that the number of bonding processes increases, and thus the cost may increase. In addition, in both the containers disclosed in JP-A-2003-179456 and JP-A-2004-166006, since a straight via electrode is used, there is a problem in that the degree of freedom of a position at which a mount terminal is provided is small. In addition, in the container disclosed in JP-A-2011-124978, it is necessary to lead out the lead-out terminals from the end portion of the quartz maintaining terminal toward the closest corner portions, respectively, and thus there is a concern that a main surface of the insulating substrate may not be used in an effective manner.

Therefore, in the container whose size is reduced and height is lowered, in order to widely utilize the inner bottom surface, as shown in a cross-sectional view of FIG. 14A, when a ceramic insulating substrate 10 is irradiated with laser light to form a through-hole 12, a vitreous layer 14 is formed on an inner wall surface of the through-hole 12. As shown in a cross-sectional view of FIG. 14B, when a metallic film 16 is formed on the vitreous layer 14 and a circuit substrate is manufactured, there is a problem in that an adhesion property between the insulating substrate 10 and the metallic film 16 becomes weak.

### SUMMARY

An advantage of some aspects of the invention is to provide a container in which an adhesion property of a metallic film formed on an inner wall surface of a through-hole is increased, the size of the container is reduced, the height of the container is lowered, and thus an inner bottom surface may be widely used, and a piezoelectric oscillator and an electronic device that use the container.

### Application Example 1

This application example is directed to a circuit substrate including: wiring conductors that are provided on two main surfaces of a single-layer insulating substrate, respectively; a first concave portion that is formed in one of the main surfaces of the single-layer insulating substrate; a second concave portion that is formed in the other of the main surfaces to partially overlap the first concave portion in a plan view; a through-portion through which the first concave portion and the second concave portion partially communicate with each other; and a through-wiring that is formed at an inner surface of a through-hole including the first concave portion, the second concave portion, and the through-portion, and that electrically connects the two wiring conductors.

According to this configuration, since the center line of an opening of the first concave portion, which is formed in one of the main surfaces, of the through-hole that is formed in a thickness direction of the single-layer insulating substrate, and the center line of an opening of the second concave portion, which is formed in the other of the main surfaces, of the through-hole are eccentric to each other, there is an effect of improving the adhesion strength of a metallic film with respect to the single-layer insulating substrate. Furthermore, there is an effect of increasing a degree of freedom of a position of the wiring conductor that is formed on one of the main surfaces and a position of the wiring conductor that is formed on the other of the main surfaces.

### Application Example 2

This application example is directed to the circuit substrate according to Application Example 1, wherein the through-portion is blocked by the through-wiring.

According to this configuration, since the through-portion of the through-hole that is formed in the single layer insulating substrate is blocked, there is an effect that the circuit substrate is applicable to a circuit substrate in which a non-communication property is required between front and rear surfaces.

### Application Example 3

This application example is directed to an electronic device including: the circuit substrate according to Application Example 1 or 2; and a cover member that is fixed to the circuit substrate, in which an electronic component accommodating space that accommodates an electronic component is formed between the circuit substrate and the cover member.

According to this configuration, when a container is constructed by using, for example, the circuit substrate described in Application Example 2 as a lower plate, since the circuit substrate is a single-layer insulating substrate, this circuit substrate is optimal for the lowering of the height, and since a crank-shaped internal conductor, which is formed by hermetically sealing (blocking) the through-portion of the through-hole is used for electrical conduction between the front and rear surfaces, a position of an element mounting electrode pad (a first electrode pad) on the front surface and a position of a mounting terminal on the rear surface may be freely set within a certain range, and thus the bottom surface inside the container may be utilized in an effective manner. As a result, there is an effect that a large piezoelectric element may be accommodated.

### Application Example 4

This application example is directed to an electronic apparatus including the electronic device described in Application Example 3.

According to this configuration, there is an effect that an electronic apparatus in which the size is reduced and the height is lowered may be constructed.

### Application Example 5

This application example is directed to a method of manufacturing a circuit substrate. The method includes: a process of preparing a single-layer insulating substrate in which wiring conductors are provided on two main surfaces, respectively; a first process of forming a first concave portion in one of the main surfaces of the single-layer insulating substrate; a second process of forming a second concave portion in the other of the main surfaces of the single-layer insulating substrate to partially overlap the first concave portion in a plan view; a third process of forming a through-portion in order for the first concave portion and the second concave portion to partially communicate with each other; and a process of forming a through-wiring on an inner surface of a through-hole having the first concave portion, the second concave portion, and the through-portion to electrically connect the two wiring conductors.

According to this manufacturing method, since the through-hole having a crank shape is formed in the single-layer insulating substrate in a thickness direction thereof and a metallic film is formed on an inner wall surface of the through-hole, a degree of freedom is given at positions on the front and rear surfaces of the wiring conductors that are provided on the front and rear surfaces of the circuit substrate, and thus there is an effect that a circuit substrate appropriate for miniaturization and lowering of the height may be constructed.

### Application Example 6

This application example is directed to the method of manufacturing a circuit substrate according to Application Example 5, wherein the first and second concave portions, and the through-portion are formed by using laser light in the first, second, and third processes.

According to this manufacturing method, since a through-hole including the first and second concave portions and the through-portion is formed by using laser light, a shape of the through-hole may be constructed freely to certain amount. Therefore, there is an effect that a circuit substrate appropriate for the miniaturization and the lowering of the height may be constructed.

### Application Example 7

This application example is directed to the method of manufacturing a circuit substrate according to Application Example 5, wherein the concave portions are formed using a mold in the first and second processes, and the through-portion is formed using laser light in the third process.

According to this manufacturing method, since the concave portions are formed in the circuit substrate using the mold, and a non-through portion is made to be penetrated using laser light, there is an effect that a manufacturing cost may be lowered.

### Application Example 8

This application example is directed to the method of manufacturing a circuit substrate according to Application Example 6 or 7, wherein an inner surface of the through-hole is ground by sandblasting after at least one of the first, second, and third processes.

According to this manufacturing method, since the inner surface of the through-hole is ground by sandblasting, there is an effect that an adhesion property between the circuit substrate and the metallic film is improved.

### BRIEF DESCRIPTION OF THE DRAWINGS

The invention will be described with reference to the accompanying drawings, wherein like numbers reference like elements.

FIGS. 1A and 1B are schematic views illustrating a configuration of a circuit substrate relating to an embodiment of the invention, in which FIG. 1A is a plan view, and FIG. 1B is a cross-sectional view taken along a line Q-Q in FIG. 1A.

FIG. 2A is cross-sectional view of a circuit substrate in which a through-portion is hermetically sealed with a metallic film, and FIG. 2B is a cross-sectional view of the circuit substrate in which a conductive material is filled in first and second concave portions, and the through-portion.

FIGS. 3A to 3E are cross-sectional views illustrating a process of forming an internal conductor in a signal layer insulating substrate in a process sequence.

FIGS. 4A to 4C are cross-sectional views illustrating another method of forming the internal conductor in the signal layer insulating substrate in a process sequence.

FIGS. 5A to 5C are cross-sectional views illustrating still another method of forming the internal conductor in the signal layer insulating substrate in a process sequence.

FIG. 6A is a plan view in which a cover member of a container is omitted, FIG. 6B is a cross-sectional view taken along a line Q-Q in FIG. 6A, FIG. 6C is a bottom view, and FIG. 6D is a cross-sectional view of a modification example of the container.

FIGS. 7A and 7B are views illustrating a configuration of a piezoelectric oscillator, in which FIG. 7A is a plan view in which a cover member is omitted, and FIG. 7B is a cross-sectional view taken along a line Q-Q in FIG. 7A.

FIG. 8 is a view illustrating coordinate axes and a cutting angle.

FIG. 9A is a plan view of a piezoelectric oscillating element, and FIG. 9B is a cross-sectional view taken along a line Q-Q in FIG. 9A.

FIGS. 10A and 10B are views illustrating a configuration of an electronic device, in which FIG. 10A is a plan view in which a cover member is omitted, and FIG. 10B is a cross-sectional view taken along a line Q-Q in FIG. 10A.

FIGS. 11A and 11B are views illustrating a configuration of an electronic device, in which FIG. 11A is a plan view in which a cover member is omitted, and FIG. 11B is a cross-sectional view taken along a line Q-Q in FIG. 11A.

FIG. 12 is a cross-sectional view illustrating a configuration of an electronic device.

FIG. 13 is a schematic view of an electronic apparatus according to an embodiment of the invention.

FIG. 14A is a cross-sectional view of a single-layer insulating substrate in which a through-hole is formed with laser light, and FIG. 14B is a cross-sectional view of the single-layer insulating substrate in which a metallic film is formed on a wall surface of the through-hole in FIG. 14A.

### DESCRIPTION OF EXEMPLARY EMBODIMENTS

Hereinafter, embodiments of the invention will be described in detail with reference to the attached drawings.

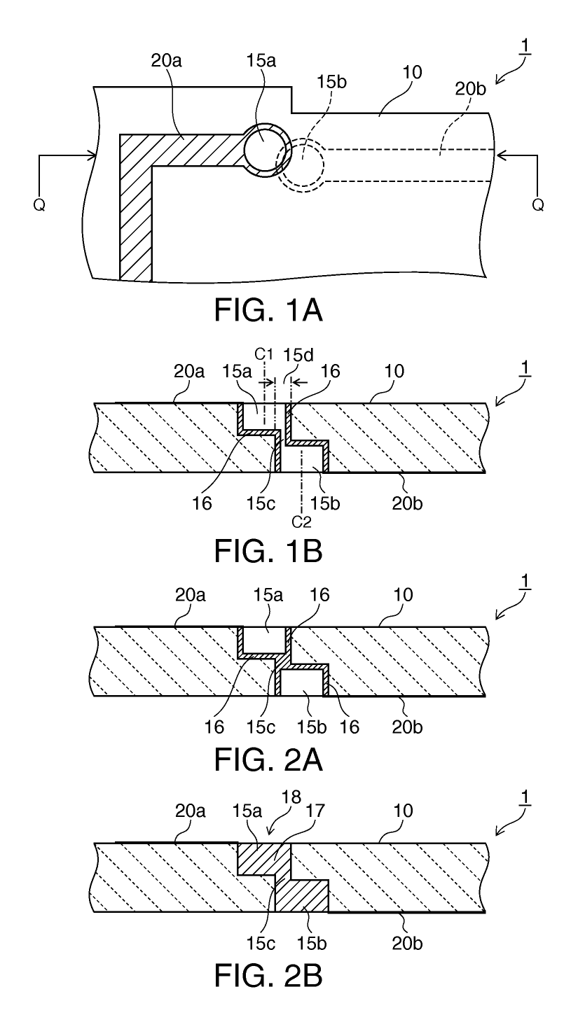

FIGS. 1A and 1B shows schematic views illustrating a configuration of a circuit substrate 1 relating to an embodiment of the invention, in which FIG. 1A shows a plan view of the circuit substrate 1, and FIG. 1B shows a cross-sectional view taken along a line Q-Q in FIG. 1A.

The circuit substrate 1 is a circuit substrate that mounts an electronic device or the like and includes a single-layer insulating substrate 10 having a flat plate shape, a through-hole 15 that penetrates through the single-layer insulating substrate 10 in a thickness direction thereof, a first wiring conductor 20a that is provided on a first main surface (front surface) of the single-layer insulating substrate 10, and a second wiring conductor 20b that is provided on a second main surface (rear surface) that is opposite to the first main surface.

The through-hole 15 that is formed to penetrate through in the thickness direction includes a first concave portion 15a that is formed in the first main surface (front surface) of the single-layer insulating substrate 10, a second concave portion 15b that is formed in the second main surface in a state in which a portion 15d is opposite to the first concave portion 15a, and a through-portion 15c that communicates with the first concave portion 15a and the second concave portion 15b.

In the circuit substrate 1, an opening area of a portion 15d at which a part of the first concave portion 15a formed in the first main surface and apart of the second concave portion 15b formed in the second main surface overlap each other in an opposite state is a half or less of an opening area of any large concave portion between the first and second concave portions 15a and 15b. In addition, a metallic film 16 is formed on respective inner wall surfaces of the first and second concave portions 15a and 15b, and the through-portion 15c by using means such as sputtering. The metallic film 16 that is formed on the inner wall surface of the first concave portion 15a is electrically connected to the first wiring conductor 20a, and the metallic film 16 that is formed on the inner wall surface of the second concave portion 15b is electrically connected to the second wiring conductor 20b. That is, the center line C2 of the second concave portion 15b does not coincide with the center line C1 of the first concave portion 15a, and the through-portion 15c is formed at the portion 15d at which both of the concave portions 15a and 15b overlap each other. In the embodiment of FIG. 1A, a case in which a shape of an aperture plane of the first and second concave portions 15a and 15b is a circle is exemplified, but the shape of the aperture plane may be an ellipse, a rectangle, or a square.

FIG. 2A is a modification example of the circuit substrate 1 shown in FIGS. 1A and 1B, and is a cross-sectional view of the circuit substrate 1 when this circuit substrate 1 is used, for example, as a bottom plate of a container accommodating an electronic component. In FIG. 2A, the through-portion 15c is blocked (hermetically sealed) by making the metallic film 16 of the through-portion 15c thick, and the first main surface (front surface) and the second main surface (rear surface) of the single-layer insulating substrate 10 enter a non-communication state. Since a plan view of the circuit substrate 1 is substantially the same as the plan view shown in FIG. 1A, the plan view is omitted. FIG. 2B is a cross-sectional view of a modification example of the circuit substrate 1 shown in FIG. 1A, and the first and second concave portions 15a and 15b and the through-portion 15c are filled with a conductive material 17, and thus the first main surface (front surface) and the second main surface (rear surface) of the single-layer insulating substrate 10 enter a non-communication state. Here, a portion in which the through-hole 15 is filled with the metallic film 16 or the conductive material 17 is called an internal conductor 18.

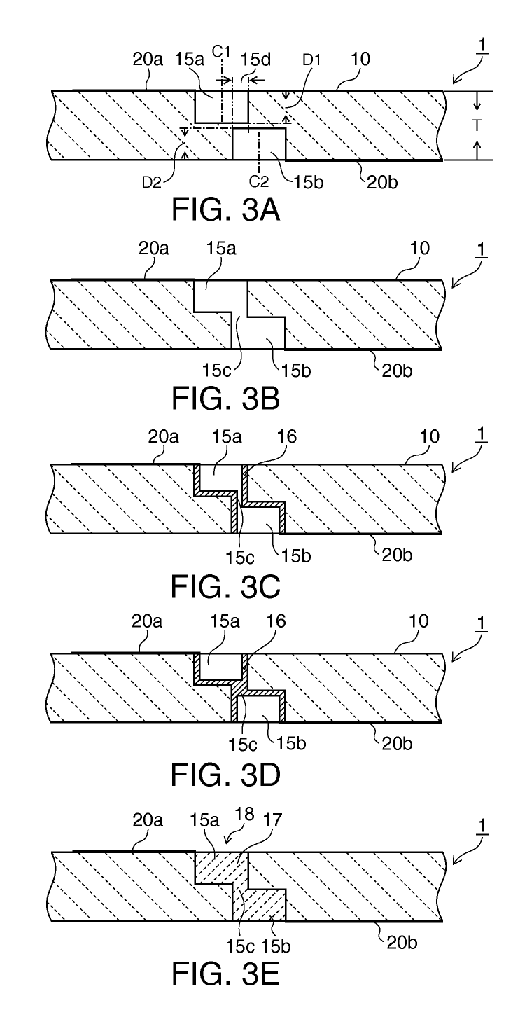

FIGS. 3A to 3E show longitudinal cross-sectional views illustrating an example of a method of forming the through-hole 15 in the single-layer insulating substrate 10. As shown in FIG. 3A, the first main surface (front surface) of the single-layer insulating substrate 10 is irradiated with laser light to form the first concave portion 15a having a predetermined size and a predetermined depth. Next, the second main surface (rear surface) is irradiated with laser light in a state in which an irradiation position is offset from the center line of the first concave portion 15a to form the second concave portion 15b having a predetermined opening area and a predetermined depth. At this time, an opening area and an opening shape of each concave portion are selected in such a manner that a part of both of the concave portions 15a and 15b overlap each other. Next, as shown in FIG. 3B, a portion at which the first concave portion 15a and the second concave portion 15b are opposite to each other, that is, the overlapping portion 15d is etched by laser light to form the through-portion 15c. That is, the first concave portion 15a and the second concave portion 15b are formed in a state in which both of the center lines C1 and C2 are offset from each other to have the portion 15d at which the first and second concave portions 15a and 15b overlap each other in a surface direction of the single-layer insulating substrate 10. In addition, the depth obtained by adding the respective depths D1 and D2 of the first and second concave portions 15a and 15b is set to be smaller than the thickness T of the single-layer insulating substrate 10. Therefore, the non-through portion 15d remains between both of the concave portions. In the cross-sectional view shown in FIG. 3B, the non-through portion 15d between the first and second concave portions 15a and 15b is entirely removed by laser light, but the through-portion 15c may be formed by removing only a part of the overlapping portion.

When the first and second concave portions 15a and 15b, and the through-portion 15c are formed in the single-layer insulating substrate 10 using laser light, a thin vitreous material is formed on the inner wall surfaces thereof. When the metallic film 16 is formed on the inner wall surfaces while this vitreous material remains, an adhesion property and the bonding strength between the vitreous material and the metallic film 16 become weak, and thus there occurs a problem that the metallic film 16 is easily peeled off. When the single-layer insulating substrate 10 is made as a thin plate, the metallic film 16 is further easily peeled off. To overcome a problem of a decrease in adhesion property and bonding force, in the embodiment of the invention, the through-hole 15 having a crank-shape in the thickness direction of the single-layer insulating substrate 10 is formed, instead of forming a straight through-hole that linearly penetrates through the single-layer insulating substrate 10 in the thickness direction thereof. Since a bonding area between the inner wall surface of the through-hole 15 and the metallic film 16 increases and the metallic film 16 is also bonded to a plane intersecting the plate thickness direction of the single-layer insulating substrate 10, the entire bonding force of the metallic film 16 increases, and thus the metallic film 16 may be prevented from being peeled off. Furthermore, when the vitreous material that is formed on the inner wall surface of the through-hole 15 is ground using, for example, means such as sandblasting to improve the adhesion strength, the adhesion property is further improved.

Next, as shown in FIG. 3C, the metallic film 16 is formed on the inner wall surface of the through-hole 15 using means such as a vacuum deposition method, a sputtering method, and an ion plating method. In a general circuit substrate, the through-portion 15c may be empty, but in the case of using the circuit substrate as a bottom plate of a container accommodating an electronic element or the like, it is necessary for the first main surface (front surface) and the second main surface (rear surface) that is opposite to the first main surface to be a non-communication state. In this use, as shown in a cross-sectional view of FIG. 3D, it is preferable that in the circuit substrate 1, the through-portion 15c be blocked (hermetically sealed) with the metallic film 16. In addition, as shown in FIG. 3E, the circuit substrate 1 may be constructed in such a manner that the first and second concave portions 15a and 15b, and the through-portion 15c are sealed with the conductive material 17.

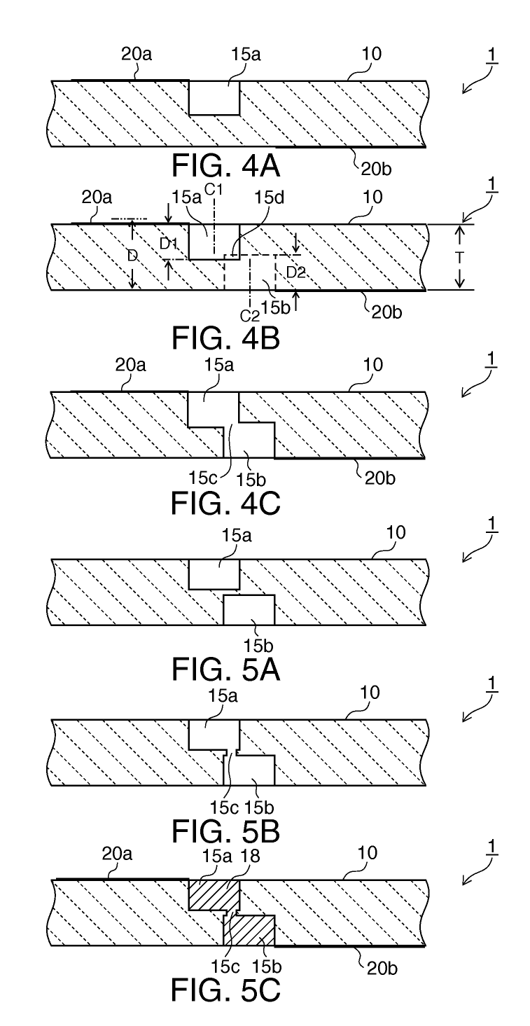

In addition, as another method of forming the through-hole 15 in the single-layer insulating substrate 10, as shown in FIG. 4A, first, the first concave portion 15a having a predetermined opening area and a predetermined depth is formed in the first main surface (front surface) of the single-layer insulating substrate 10 using laser light. Next, as indicated by a broken line of FIG. 4B, the second concave portion 15b having a predetermined opening area and a predetermined depth is formed in the second main surface (rear surface) that is opposite to the first main surface (front surface) using laser light. At this time, a position of the center line C2 of the second concave portion 15b is made to be offset from that of the center line C1 of the first concave portion 15a, but both of the concave portions 15a and 15b are made to partially overlap each other. Furthermore, a depth D obtained by adding the respective depths D1 and D2 of the first and second concave portions 15a and 15b is set to be larger than the thickness T of the single-layer insulating substrate 10. The setting is made in this way, and the through-portion 15c is formed at a portion at which the first and second concave portions 15a and 15b overlap each other. The vitreous material, which is formed on the inner wall surface of the through-hole 15, is removed using sandblasting as described in FIGS. 3A to 3E. In addition, the forming of the metallic film 16 on the inner wall surfaces of the first and second concave portions 15a and 15b and the inner wall surface of the through-portion 15c after removing the vitreous material is similar to a case of FIG. 3A to 3E.

In addition, as another method of forming the through-hole 15 in the single-layer insulating substrate 10, a method in which when a ceramic green sheet is made to pass through between two rollers at a ceramic green sheet stage, a through-hole (concave portions 15a and 15b) is formed by convex portions provided on peripheral surfaces of both of the rollers may be exemplified. That is, when the ceramic green sheet is made to pass through between the rollers in a state in which the two rollers are disposed to be opposite to each other so that the peripheral surfaces thereof are adjacent to each other, the through-hole is punched by the convex portions formed on the peripheral surfaces of the rollers. After undergoing this process, as shown in FIG. 5A, the first and second concave portions 15a and 15b whose center lines are offset from each other are formed on the front and rear surfaces. Next, this ceramic green sheet is made to pass through between a pair of through-portion forming rollers that is disposed at a next stage. That is, when the ceramic green sheet is made to pass through between one side roller to which a needle-shaped protrusion is provided on a peripheral surface thereof and another roller that is disposed to be opposite to the one side roller, the through-portion 15c is formed by the needle-shaped protrusion at a portion at which the first and second concave portions 15a and 15b overlap each other in the surface direction thereof. The circuit substrate may be constructed in such a manner that the first and second wiring conductors 20a and 20b are screen-printed on the front and rear surfaces of the green sheet, via electrode paste is filled in the through-hole 15 (the first and second concave portions 15a and 15b, and the through-portion 15c), and the green sheet is baked at a high temperature.

As shown in the embodiment of FIGS. 1A to 5C, since the center line of an opening of the first concave portion 15a of one main surface (first main surface) of the through-hole 15 that is formed in the thickness direction of the single-layer insulating substrate 10 and the center line of an opening of the second concave portion 15b of the other main surface (second main surface) are made to be offset from each other in a position thereof, an internal conductor has a crank shape, and thus there is an effect that the adhesion strength of the metallic film 16 with respect to the single-layer insulating substrate 10 is improved. Furthermore, a degree of freedom of a position of the wiring conductor 20a that is formed in one main surface (first main surface) and a position of the wiring conductor 20b that is formed in the other main surface (second main surface) increases, and thus this is effective for miniaturization.

Furthermore, since the through-portion 15c of the through-hole 15, which is formed in the single-layer insulating substrate, is blocked, there is an effect that this circuit substrate is applicable to a circuit substrate in which a non-communication property between the front and rear surfaces (first and second main surfaces) is required.

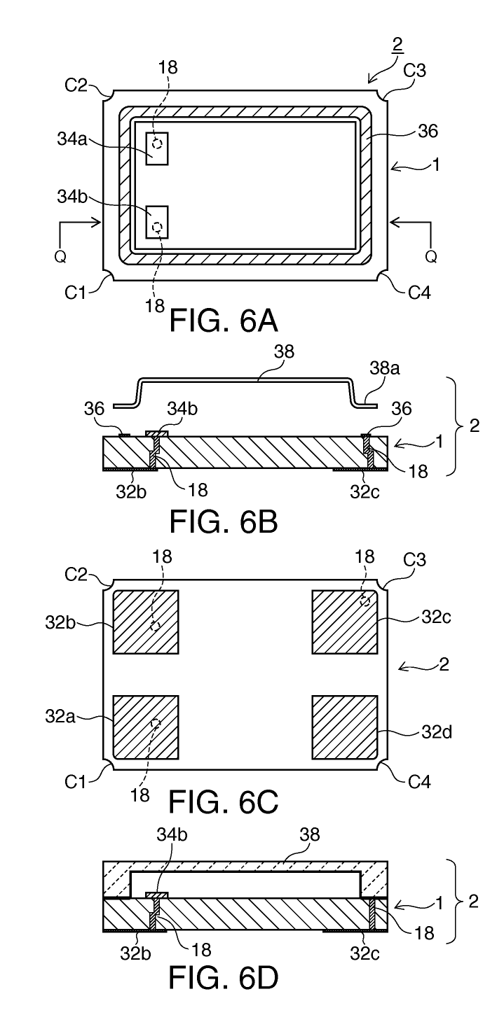

FIGS. 6A to 6D show schematic views illustrating a configuration of a container 2 for an electronic component of an embodiment of the invention, in which FIG. 6A shows a plan view, FIG. 6B is a cross-sectional view taken along a line Q-Q in FIG. 6A, and FIG. 6C is a bottom view. The container 2 includes the circuit substrate 1 in which the crank-shaped internal conductor 18 is formed inside a single-layer insulating substrate 30, and a cover member 38 that covers a front-side space of the circuit substrate 1 shown in FIGS. 2A and 2B. The circuit substrate 1 is used as a bottom plate of the container, and thus it is necessary for the first main surface (front surface) and the second main surface (rear surface) of the circuit substrate to be a non-communication state. The circuit substrate 1 includes a pair of first electrode pads 34a and 34b that is provided in parallel with each other in the vicinity of an end portion of the first main surface (front surface) in a longitudinal direction thereof along a lateral direction of the first main surface. Furthermore, mounting terminals 32a, 32b, 32c, and 32d, which are connected to a main wiring substrate (main board), are provided at corner portions of the second main surface (rear surface) opposite to the first main surface. The pair of first electrode pads 34a and 34b, and the mounting terminals 32a and 32b are electrically connected to each other by the internal conductor 18 that is formed by filling the conductive material 17 in the through-hole 15 as described with reference to FIGS. 3A to 3E. In addition, one of the mounting terminals, for example, the mounding terminal 32c is electrically connected to the seal ring 36 by the internal conductor 18.

The cover member 38 is obtained by processing a metallic plate having a flat plate shape into a reversed concave shape (a reverse bowl shape) using a pressing machine, and thus a flange portion 38a, which is flared toward the outside, is formed at an opening-side peripheral edge (hem portion). The cover member 38 is placed on the seal ring 36, and the flange portion 38a of the cover member 38 is melted by irradiation of laser light, whereby the seal ring 36 and the cover member 38 are air-tightly sealed. In this manner, since the internal conductor 18, which is bent in a crank shape, is used, an adhesion property between the single-layer insulating substrate 30 of the circuit substrate 1 and the internal conductor 18 is reinforced, and the first main surface (front surface) and the second main surface (rear surface) of the circuit substrate 1 may be used in an effective manner. That is, there is an advantage in that a degree of selection freedom (a degree of layout freedom) of positions, at which the first electrode pads are provided, and positions from which wiring patterns are led out and at which the mounting terminals are provided, increases.

FIG. 6D shows a modification example of the container 2, and the cover member 38 is formed from non-metal such as ceramic and glass in a reverse bowl shape. In this case, a glass member is applied on a peripheral edge of the top surface of the single-layer insulating substrate 30, this glass member is melted to fix the cover member 38 to this peripheral edge. The inner side of the cover member may be subjected to a metallization process.

For example, when the container 2, which accommodates an electronic element, is constructed by using the circuit substrate 1 shown in FIGS. 2A and 2B as a bottom plate like the embodiment shown in FIGS. 6A to 6D, since the circuit substrate 1 is a thin single-layer insulating substrate 10, this circuit substrate 1 is optimal for the lowering of the height, and since the crank-shaped internal conductor 18, which is formed by hermetically sealing (blocking) the through-portion 15c of the through-hole 15, is used for electrical connection between the front and rear surfaces of the single-layer insulating substrate 10, a position of the first electrode pad (element mounting electrode pad) on the front surface and a position of the mounting terminals 32b and 32c on the rear surface may be freely set within a certain range, and thus the bottom surface inside the container 2 may be utilized in an effective manner, and thus there is an effect that a large piezoelectric element may be accommodated.

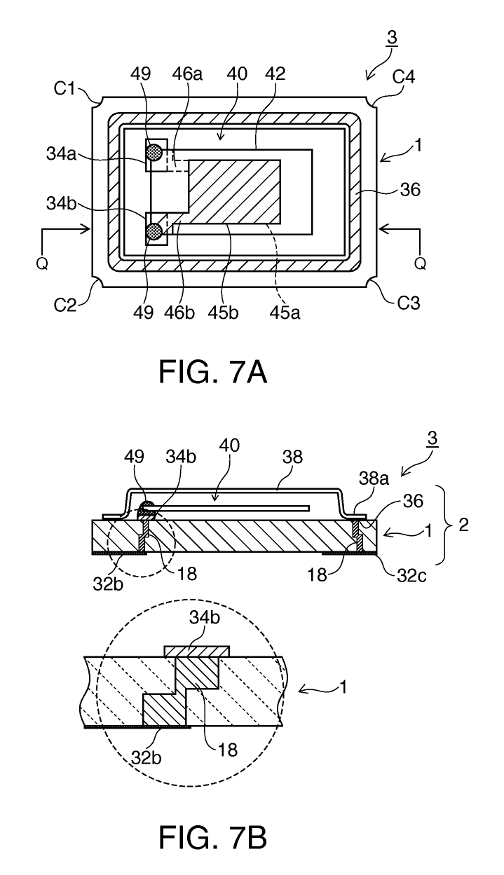

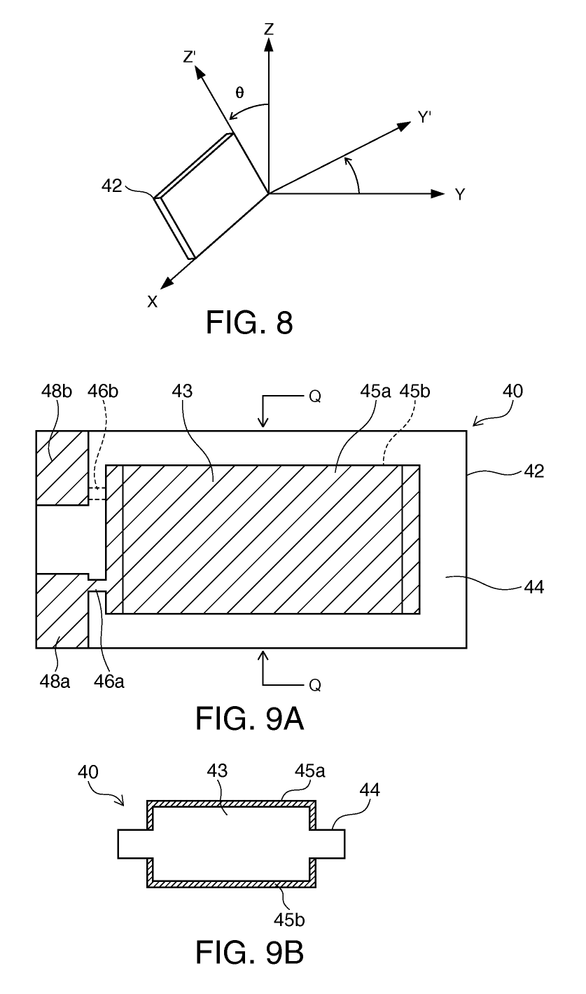

FIGS. 7A and 7B show schematic views illustrating a configuration of a piezoelectric oscillator 3 of an embodiment of the invention, in which FIG. 7A shows a plan view in which a cover member is omitted, and FIG. 7B shows a cross-sectional view taken along a line Q-Q in FIG. 7A. The piezoelectric oscillator 3 includes a piezoelectric oscillating element 40, and the container 2 that accommodates the piezoelectric oscillating element 40. As described with reference to FIGS. 6A to 6D, the container 2 includes the circuit substrate 1 and a cover member 38. As the piezoelectric oscillating element 40 that is used in the embodiment of FIGS. 7A and 7B, for example, an AT-cut quartz oscillating element may be exemplified. A piezoelectric material such as quartz belongs to a trigonal system, and has crystal axes X, Y, and Z that are orthogonal to each other as shown in FIG. 8. The X-axis, Y-axis, and Z-axis are called an electric axis, a mechanical axis, and an optical axis, respectively. The At-cut quartz substrate 42 is a flat plate obtained by cutting quartz along a plane when an X-Z plane is rotated around the X-axis by an angle θ. In the case of the AT-cut quartz substrate 42, θ is substantially 35°15′. In addition, the Y-axis and the Z-axis are also rotated by θ along the X-axis and are set to a Y′-axis and a Z′-axis. Therefore, the AT-cut quartz substrate 42 has crystal axes X, Y′, and Z′ that are orthogonal to each other. In the AT-cut quartz substrate 42, the thickness direction is the Y′-axis, an XZ′-plane (plane including the X-axis and the Z′-axis) that is orthogonal to the Y′-axis is a main surface, and thickness sliding oscillation is excited as main oscillation. Even though a cut angle other than AT-cut is different, a BT-cut may be used.

That is, an example of the piezoelectric substrate 42 shown in FIGS. 7A and 7B is formed from an AT-cut quartz substrate that is constructed by a plane parallel with the X-axis and a Z′-axis in which, as shown in FIG. 8, an axis obtained by inclining the Z-axis in a −Y direction of the Y-axis is set to the Z′-axis, and an axis obtained by inclining the Y-axis in a +Z direction of the Z-axis is set to a Y′-axis with the X-axis of an orthogonal coordinate system including the X-axis (electric axis), the Y-axis (mechanical axis), and the Z-axis (optical axis) made as the center. In the AT-cut quart substrate, a direction parallel with the Y′-axis is set to the thickness direction.

An external shape of the AT-cut quartz substrate is generally a rectangular shape in which the X-axis direction is set to a longitudinal direction, and a resonance frequency depends on the thickness in the Y′-axis direction. In a case where a frequency is high, and an X side ratio (X/t; here, X represents a length in the X-axis direction and t represents a thickness), or a Z side ratio (Z/t; here, Z represents a length in the Z′-axis direction and t represents a thickness) is large, the flat-shaped quartz substrate 42 is used as shown in FIGS. 7A and 7B. In addition, in a case where a frequency is low, and the X side ratio (X/t) or the Z side ratio (Z/t) is small, a mesa-type quartz substrate (a quartz substrate in which a central portion is made to be thicker than a peripheral portion) 42 is used. FIGS. 9A and 9B show an example of the mesa-type quartz oscillating element, in which FIG. 9A shows a plan view and FIG. 9B shows a cross-sectional view taken along a line Q-Q.

The mesa-type quartz substrate 42 includes an excitation portion 43 that is located at the center thereof and becomes a main oscillation region, and a peripheral portion 44 that is thinner than the excitation portion 43 and that becomes an oscillation region formed along the periphery of the excitation portion 43. That is, the oscillation region extends over the excitation portion 43 and a part of the peripheral portion 44. An example shown in FIGS. 9A and 9B is an example of the piezoelectric oscillating element 40 using a mesa-type piezoelectric substrate in which two-stage step difference is formed in a longitudinal direction (a transverse direction in the drawings) of the piezoelectric substrate 42, and as shown in FIG. 9B, one-stage step difference is formed in a lateral direction (a vertical direction in the drawings).

In the piezoelectric oscillating element 40, excitation electrodes 45a and 45b are formed on front and rear surfaces of the excitation portion 43 of the quartz substrate 42, and lead electrodes 46a and 46b, which extend from the excitation electrodes 45a and 45b toward terminal electrodes 48a and 48b provided at an end portion of the quartz substrate 42, respectively, are formed.

When an alternating voltage is applied to the excitation electrodes 45a and 45b, the quartz oscillating element 40 is excited in an intrinsic oscillation mode. For example, in the case of the AT-cut quartz, excitation occurs in a thickness sliding mode.

A sequence of constructing the piezoelectric oscillator 3 shown in FIGS. 7A and 7B is as follows. A conductive adhesive 49 is applied to the pair of first electrode pads 34a and 34b that are formed on the first main surface of the circuit substrate 1 making up the container 2, and the piezoelectric oscillating element 40 as shown in FIGS. 9A and 9B, which is prepared in advance, is placed on the circuit substrate 1 and is slightly pressed. The resultant product is placed in a drying furnace and is heated at a predetermined temperature for a predetermined time to carry out drying of the conductive adhesive 49 and annealing of the piezoelectric oscillating element 40. Then, the cover member 38 is welded to the seal ring 36 that is formed at an upper periphery of the circuit substrate 1 in a vacuum atmosphere or an inert gas atmosphere to air-tightly seal these, whereby the piezoelectric oscillator 3 is completed. In a case where the piezoelectric oscillator 3 in which a CI value (a crystal impedance value) is small is required, it is preferable that the inside of the container 2 (the circuit substrate 1 and the cover member 38) be set to a vacuum state. In addition, an inert gas such as nitrogen N₂ may be used in accordance with a standard.

Since the piezoelectric oscillator 3 uses the container 2 that uses the circuit substrate 1 in which the crank-shaped internal conductor 18 is formed inside the single-layer insulating substrate 10, the piezoelectric oscillator 3 has a degree of freedom of positions at which the first electrode pads 34a and 34b are provided. That is, the inner bottom surface of the container 2 becomes wide, and thus it is possible to accommodate the piezoelectric oscillating element 40 that is relatively large.

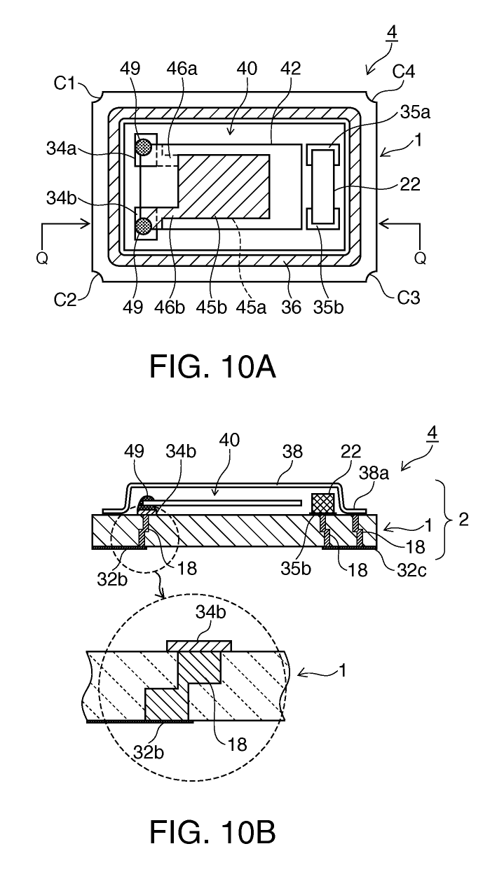

FIGS. 10A and 10B show schematic views illustrating a configuration of an electronic device 4 according to an embodiment of the invention, in which FIG. 10A shows a plan view in which the cover member 38 is omitted, and FIG. 10B shows a cross-sectional view taken along a line Q-Q in FIG. 10A. The electronic device 4 includes the piezoelectric oscillating element 40 that determines a frequency, an electronic element 22, and the container 2 that accommodates the piezoelectric oscillating element 40 and the electronic element 22. As described above, the container 2 includes the circuit substrate 1, and the cover member 38 that forms an accommodation space for accommodating an electronic element to be mounted on the circuit substrate.

In the circuit substrate 1, the pair of first electrode pads 34a and 34b that is formed in the vicinity of an end portion of the first main surface (front surface) in a longitudinal direction thereof along a lateral direction of the first main surface. Furthermore, a pair of second electrode pads 35a and 35b is formed in the vicinity of the other end portion of the first main surface (front surface) in the longitudinal direction thereof along a lateral direction of the first main surface. The mounting terminals 32a, 32b, 32c, and 32d are provided at corner portions of the second main surface (rear surface) opposite to the first main surface.

The pair of first electrode pads 34a and 34b, and the mounting terminals 32a and 32b are electrically connected to each other by the crank-shaped internal conductor 18 (indicated by being enlarged in a broken line circle). The pair of second electrode pads 35a and 35b and the mounting terminals 32b and 32d are electrically connected by the internal conductor 18. One of the mounting terminals, for example, the mounting terminal 32c is electrically connected to the seal ring 36 by the internal conductor 18.

As described above as an example, as the cover member 38, a cover that is obtained by pressing a metal plate into a reversed concave shape (a reverse bowl shape) is used.

The pair of terminal electrodes 48a and 48b of the piezoelectric oscillating element 40 is bonded and fixed on the pair of first electrode pads 34a and 34b of the circuit substrate 1 of the container 2 through the conductive adhesive 49. That is, the excitation electrodes 45a and 45b are electrically connected to the mounting terminals 32a and 32b through the first electrode pads 34a and 34b. Furthermore, a pair of terminal electrodes 22a and 22b of the electronic element (for example, a temperature-sensitive component) 22 is bonded and fixed on the pair of second electrode pads 35a and 35b of the circuit substrate 1 through the conductive adhesive 49. The electronic element (for example, a temperature-sensitive component) 22 is electrically connected to the mounting terminals 32c and 32d through the second electrode pads 35a and 35b, and one mounting terminal, for example, the mounting terminal 32c is frequently grounded on the main circuit substrate. In addition, when the mounting terminal 32c is electrically connected to the internal conductor 18 by the seal ring 36, and thus the sealing terminal 32c is grounded, the cover member 38 is grounded and thus a shield effect may be provided. As an example of the electronic element 22, a thermistor in which a physical quantity thereof, for example, an electrical resistance is changed in response to a variation in temperature, and the like may be used. A variation in electrical resistance of the thermistor 22 is detected by an external circuit, and a temperature of the thermistor 22 is measured. A temperature of the piezoelectric oscillating element 40 may be assumed from the temperature of the thermistor 22, and thus a frequency of the piezoelectric oscillating element 40 may be compensated by an external circuit.

Since the electronic element 22 is accommodated on the bottom surface of the container 2 of the piezoelectric oscillator 4 like the embodiment shown in FIGS. 10A and 10B, for example, when a temperature-sensitive element is used as the electronic element, there is an effect that a temperature compensation type piezoelectric oscillator may be constructed by connecting the temperature-sensitive element to an external oscillation circuit and a temperature compensation circuit.

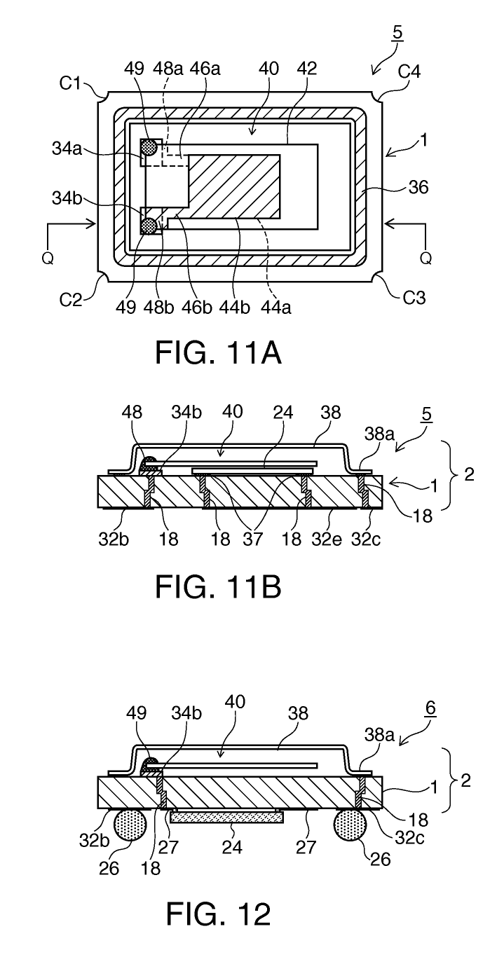

FIGS. 11A and 11B show schematic views illustrating a configuration of an electronic device 5 of an embodiment of the invention, in which FIG. 11A shows a plan view in which the cover member 38 is omitted, and FIG. 11B shows a cross-sectional view taken along a line Q-Q in FIG. 11A. The electronic device 5 includes the piezoelectric oscillating element 40, an IC component 24 that causes the piezoelectric oscillating element 40 to oscillate and compensates an oscillated frequency, and the container 2 that accommodates the piezoelectric oscillating element 40 and the IC component 24. The container 2 includes the circuit substrate 1 serving as a bottom plate, and the cover member 38 that forms an accommodation space for accommodating an electronic element to be mounted on the circuit substrate 1.

In the circuit substrate 1, the pair of first electrode pads 34a and 34b that is formed in the vicinity of one end portion of the first main surface (front surface) in a longitudinal direction thereof along a lateral direction of the first main surface. Furthermore, a third electrode pad 37 on which an IC component is mounted is formed at a central region of the first main surface (front surface), and the seal ring 36 is formed at the periphery of the first main surface. In addition, the mounting terminals 32a, 32b, 32c, 32d, and 32e are provided at corner portions of the second main surface (rear surface) opposite to the first main surface. The pair of first electrode pads 34a and 34b, and the mounting terminals 32a and 32b are electrically connected to each other by the crank-shaped internal conductor 18 as described above with reference to FIGS. 3A to 3E. The third electrode pad 37 (in plural numbers) and the mounding terminal 32e (in plural numbers) are electrically connected by the internal conductor 18 (in plural numbers). One of the mounting terminals, for example, the mounting terminal 32c is electrically connected to the seal ring 36 by the internal conductor 18.

The third electrode pad 37 (in plural numbers) is connected to an external terminal of the IC component 24, for example, using a metallic bump in a thermal compression manner. Since the first electrode pads 34a and 34b are provided at a position higher than that of the third electrode pad 37, the piezoelectric oscillating element 40 is spaced to the upper side of the IC component 24, and is bonded and fixed to the first electrode pads 34a and 34b through the conductive adhesive 49. The cover member 38 is placed on the seal ring 36 that is formed on the first main surface of the circuit substrate 1, and the flange portion 38a of the cover member 38 is melted and welded by irradiation of laser light in a vacuum atmosphere or an inert gas atmosphere, whereby the seal ring 36 and the cover member 38 are air-tightly sealed. Since the electronic device 5 is constructed by using the circuit substrate 1 according to the invention, miniaturization and lowering of the height of the electronic device 5 may be realized, and an internal bottom surface of the electronic device 5 may be used in an effective manner, and thus the piezoelectric oscillating element 40 having a large size may be mounted. In addition, the seal ring 36 is frequently used in a state in which the seal ring 36 is connected to the mounting terminal 32c by the internal conductor 18 and is grounded.

When an electronic device is constructed like the embodiment shown in FIGS. 11A and 11B, there is an effect that a temperature compensation type piezoelectric oscillator whose size is reduced and height is lowered may be constructed.

FIG. 12 shows a cross-sectional view illustrating a configuration of an electronic device 6 of an embodiment of the invention. The electronic device 6 is different from the electronic device 5 shown in FIGS. 11A and 11B in that the IC component 24 is disposed at the outside of the container 2, and an external terminal of the IC component 24 is connected to the third electrode pad 37 (in plural numbers) that is formed on the second main surface (rear surface) of the circuit substrate 1. Since the IC component 24 is disposed at the outside of the container 2, a conductive connection member 26 having a dimension larger than the height of the IC component 24 is connected and fixed to the mounting terminals 32b and 32c, and the like by a conductive material to secure a space of the IC component 24. As the conductive connection member 26, a spherical metallic ball, a resin ball whose surface is treated with a metal, and the like may be used. In addition, it is not necessarily necessary for the conductive connection member 26 to have a spherical shape, and a cylindrical shape, a rectangular parallelepiped shape, or a cubic shape is also possible.

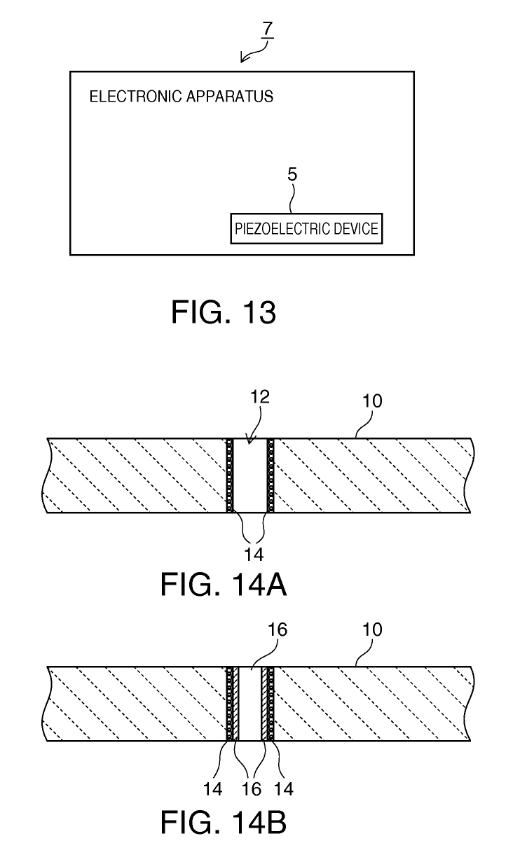

FIG. 13 shows a schematic view illustrating a configuration of an electronic apparatus 7 of an embodiment of the invention. The electronic apparatus 7 includes at least one of the piezoelectric oscillator 3 shown in FIGS. 7A and 7B, and the electronic device 4, the electronic device 5, and the electronic device 6 that are shown in FIGS. 10A and 10B, FIGS. 11A and 11B, and FIG. 12, respectively, or two or more of these.

As shown in FIG. 3A to FIG. 5C, since the crank-shaped through-hole 15 is formed in the single-layer insulating substrate 10 in the thickness direction thereof, and the metallic film 16 is formed on the inner wall surface of the through-hole 15, a degree of freedom of a position of the wiring conductors that are provided on the front and rear surfaces of the circuit substrate 1 is improved, and thus there is an effect that a circuit substrate that is suitable for the miniaturization and the lowering of the height may be constructed.

In addition, the through-hole 15 including the first and second concave portions 15a and 15b, and the through-portion 15c shown in FIGS. 3A to 5C is formed using laser light, a shape of the through-hole 15 may be constructed freely to certain amount. Therefore, there is an effect that a circuit substrate appropriate for the miniaturization and the lowering of the height may be constructed.

In addition, since the first and second concave portions 15a and 15b are formed in the single-layer insulating substrate 10 using the mold, and the non-through portion is made to be penetrated using laser light, there is an effect that a manufacturing cost may be lowered. In addition, since the inner surface of the through-hole 15 is ground by sandblasting, there is an effect that an adhesion property between the circuit substrate and the metallic film is improved.

The entire disclosure of Japanese Patent Application No. 2011-236931, filed Oct. 28, 2011, is expressly incorporated by reference herein.

What is claimed is:

1. A circuit substrate, comprising:
wiring conductors that are provided on two main surfaces, which are opposite to each other, of a single-layer substrate, respectively;
a first concave portion that is disposed on one main surface side of the single-layer substrate;
a second concave portion that is disposed on the other main surface side to partially overlap the first concave portion in a plan view;
a through-portion through which the first concave portion and the second concave portion partially communicate with each other; and
a through-wiring that is disposed at inner surfaces of the first concave portion, the second concave portion, and the through-portion, and that electrically connects the two wiring conductors.

2. The circuit substrate according to claim 1,
wherein the through-portion is blocked by the through-wiring.

3. An electronic device, comprising:
the circuit substrate according to claim 1; and
a cover member that is fixed to the circuit substrate, in which an electronic component accommodating space that accommodates an electronic component is formed between the circuit substrate and the cover member.

4. An electronic device, comprising:
the circuit substrate according to claim 2; and
a cover member that is fixed to the circuit substrate, in which an electronic component accommodating space that accommodates an electronic component is formed between the circuit substrate and the cover member.

5. An electronic apparatus, comprising:
an electronic device including the circuit substrate according to claim 1, and a cover member that is fixed to the circuit substrate, in which an electronic component accommodating space that accommodates an electronic component is formed between the circuit substrate and the cover member.

6. An electronic apparatus, comprising:
an electronic device including the circuit substrate according to claim 2, and a cover member that is fixed to the circuit substrate, in which an electronic component accommodating space that accommodates an electronic component is formed between the circuit substrate and the cover member.

7. A method of manufacturing a circuit substrate, the method comprising:
preparing a single-layer substrate in which two wiring conductors are provided on two main surfaces opposite to each other, respectively;
forming a through-hole that includes a first concave portion that is formed in one main surface side of the single-layer substrate, a second concave portion that is formed in the other main surface side of the single-layer substrate and that partially overlaps the first concave portion in a plan view, and a through-portion through which the first concave portion and the second concave portion partially communicate with each other; and
forming a through-wiring on inner surfaces of the first concave portion, the second concave portion, and the through-portion to electrically connect the two wiring conductors to each other.

8. The method of manufacturing a circuit substrate according to claim 7,
wherein the first and second concave portions and the through-portion are formed using laser light.

9. The method of manufacturing a circuit substrate according to claim 7,
wherein the first and second concave portions are formed using a mold, and the through-portion is formed using laser light.

10. The method of manufacturing a circuit substrate according to claim 8,
wherein an inner surface of the through-hole is ground by sandblasting.
